(19) United States
(12) Patent Application Publication
(10) Pub. No.: US 2007/0164403 A1
(43) Pub. Date: Jul. 19, 2007

(54) Semiconductor package structure and fabrication method thereof

(75) Inventors: Chien-Ping Huang, Hsinchu Hsein (TW); Chin-Huang Chang, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/633,876

(22) Filed: Dec. 4, 2006

(30) Foreign Application Priority Data
Jan. 16, 2006 (TW) 095101561

(51) Int. Cl. H01L 23/495

(52) U.S. Cl. 257/666

(57) ABSTRACT

A semiconductor package structure and a fabrication method thereof are provided. A semiconductor chip having an active surface and an inactive surface is coupled to a substrate. A plurality of bond pads are formed on the active surface of the semiconductor chip. The substrate can be arranged to expose the bond pads. The semiconductor chip is further attached to a lead frame having a plurality of leads, each of which has an inner portion and an outer portion higher than the inner portion, such that the semiconductor chip can be accommodated in the inner portions of the leads. An encapsulant is formed to cover the semiconductor chip and the substrate, and bottom surfaces of the leads of the lead frame are exposed from the encapsulant, so as to form a thin and compact package structure, which can package various semiconductor chips having different arrangements of bond pads.

### FIELD OF THE INVENTION

The present invention relates to semiconductor packages and fabricating methods thereof, and more particularly to a leadframe-based semiconductor package and a fabrication method thereof.

### BACKGROUND OF THE INVENTION

Conventionally, a thin small outline package (TSOP) is formed by attaching a semiconductor chip to a leadframe having a plurality of leads on its two sides and then forming an encapsulant to encapsulate the semiconductor chip and utilizing the leads on the two sides of the leadframe to electrically connect the chip to an external device.

A cross-sectional schematic view of a conventional TSOP is shown in FIG. 1, comprising a leadframe 11 having a die pad 111 and a plurality of leads 112 on two sides of the die pad 111; a semiconductor chip 10 electrically connected to the leads 112 via bonding wires 12; and an encapsulant 13 for encapsulating the chip 10, bonding wires and part of the leads 112. The semiconductor chip 10 is electrically connected to the external device via the leads 112 exposed from the encapsulant 13.

In order to improve the electrical connection between the semiconductor chip and the leads, so as to improve the electrical performance and functionality, a semiconductor package disclosed by U.S. Pat. No. 5,780,925 is proposed which involves directly attaching the semiconductor chip to the leads to form a Chip on Lead TSOP package (COL TSOP). As shown in FIG. 2, a leadframe 21 without a die pad is prepared. The leadframe 21 consists of a plurality of long leads 211 and short leads 212 abreast from each other. The chip 20 is attached directly to the long leads 211 and electrically connected to the long leads 211 and the short leads 212 via bonding wires 22. Then, an encapsulant 23 is formed to encapsulate the chip 20, bonding wires 22, and the inner portions of the long and short leads 211, 212.

One problem with the foregoing semiconductor package is that the leads must be protruded from the encapsulant to be able to electrically connect the package to an external device such as printed circuit board, and this protruding design will occupy a relatively large area of the printed circuit board compared to the overall package size.

In order to solve this problem, U.S. Pat. Nos. 5,363,279, 6,030,858 and 6,399,420 disclose a bottom lead package (BLP) in which the bottom surfaces of the leads are exposed. As shown in FIG. 3, a semiconductor package disclosed by U.S. Pat. No. 5,363,279 is provided, in which a lead frame 31 has double leads 311. Each lead 311 has an inner portion 311a and an outer portion 311b. The outer portion 311b is bent downwardly from the inner portion 311a, allowing a semiconductor chip 30 having a plurality of bond pads 300 on the active surface thereof to be attached to the inner portion 311a of the leads 311. In the design, an encapsulant 33 is formed to encapsulate the semiconductor chip 30, bonding wires 32, and the leadframe 31, allowing the outer portion 311b of the leads 311 to be exposed for electrical connection with a printed circuit board.

However, facing the challenging demands of multi-functional electronic products, the foregoing package structure cannot be stacked to increase the overall electrical performance, and thus is inherent with a serious limitation.

In addition, this type of package structure is mostly suitable for semiconductor chips that have bond pads concentrated at the center. It is not that suitable for packages haring a chip's bond pads employing cross-type, I-type arrangement or the mixture of the cross and I-type arrangement designs.

Accordingly, U.S. Pat. Nos. 5,986,209 and 6,030,858 disclose a type of semiconductor package that can be stacked on top of each other. As shown in FIG. 4A, in the semiconductor package disclosed by U.S. Pat. No. 5,986,209, the outer portion 411b of the leads is exposed from the bottom surface of the encapsulant 43 and then bent upwardly to the top surface of the encapsulant 43, allowing the outer leads 411b that are exposed from the bottom of the encapsulant of an upper semiconductor package to be stacked on the outer leads 411b that are exposed at the top surface of the lower semiconductor package. However this type of configuration is still not suitable to be used in semiconductor packages for packaging a chip that have pads arranged with a cross, I-type or a combination of cross and I-type arrangement.

In another design, as shown in FIG. 4B, U.S. Pat. No. 6,630,729 discloses a Dual Flat No Lead (DFN) package, wherein a semiconductor chip 40′ is attached to a leadframe having a plurality of leads 411′ and electrically connected to the leads 411′ via bonding wires 42′, allowing the top and bottom surfaces of the leads 411′ to be exposed from the encapsulant 43′. In this configuration, the leads 411′ protruding from the bottom of the encapsulant of one semiconductor package can be electrically connected to the leads 411′ protruding from the top of the encapsulant of the other semiconductor package. However, this type of package cannot be used for semiconductor chips that have pads arranged at the center, or in cross-type or I-type arrangement such as a DRAM chip.

Additionally, the different types of semiconductor packages described above are all not suitable for disposing passive components, thereby limiting the ability for the package to enhance the electronic performance.

### SUMMARY OF THE INVENTION

In accordance with the foregoing drawbacks of the conventional technology, a primary objective of the present invention is to provide a semiconductor package that is suitable for accommodating semiconductor chips with different bond pad arrangements, and the fabrication method thereof.

Another objective of the invention is to provide a semiconductor package with no outer leads and is thin and compact in structure, and the fabrication method thereof.

A further objective of the invention is to provide a semiconductor package that is suitable for stacking, and the fabrication method thereof, so as to increase the applicability.

Yet another objective of the invention is to provide a semiconductor package in which passive components can be accommodated so as to increase the electronic performance, and the fabrication method thereof.

In order to achieve the foregoing and other objectives, the semiconductor package of the invention comprises: a semiconductor chip having an active surface whereon a plurality of bonding pads are disposed and an opposing non-active surface; a substrate attached on the active surface in a way that the bonding pads are exposed; bonding wires for electrically connecting the bond pads of the semiconductor chip and the substrate; a leadframe having a plurality of leads whereon the semiconductor chip is accommodated and electrically connected thereto; and an encapsulant for encapsulating the semiconductor chip, substrate, and the leadframe, wherein at least the bottom surfaces of the leads of the leadframe are exposed from the encapsulant and in which the leads are divided into two sections, an inner portion and an outer portion that are formed with a differential heights, the height of the outer portion of the leads being larger than the height of the inner portion, and the semiconductor chip and the substrate being attached to the inner portion of the leads.

The fabricating method of the semiconductor package of the invention, comprises: preparing a semiconductor chip having an active surface whereon a plurality of bond pads are formed and an opposing non-active surface, the semiconductor chip being attached to a substrate via its active surface in such a way that the bond pads on the active surface are exposed to be electrically connected with the substrate; placing the semiconductor chip that has been coupled to a substrate to a leadframe having a plurality of leads and electrically connecting the semiconductor chip to the leadframe; and forming an encapsulant to encapsulate the semiconductor chip, substrate and the leadframe, wherein the bottom surfaces of the leads are exposed from the leadframe.

In other preferred embodiments, the substrate attached on the active surface of the semiconductor chip is formed with an opening to expose the bond pads of the semiconductor chip so that the bond pads can be electrically connected to the substrate via bonding wires, the size of the substrate being larger, smaller, or equal to the size of the semiconductor chip and the substrate being electrically connected to the leads of the leadframe via bonding wires or via other conductive materials such as solder balls; the leads of the leadframe are arranged on two sides of the leadframe, allowing the semiconductor chip coupled with a substrate to be attached to the inner portion of the leads via the chip or the substrate; the top surface of the outer leads being exposable from the encapsulant so as to allow stacking another package on the top; a die pad can be provided at the center of the leadframe so as to accommodate the semiconductor chip; and, in addition, the active surface of the semiconductor chip can be arranged with a plurality of substrates whose sizes are smaller than the chip, in such a way that the bond pads on the active surface of the semiconductor chip are electrically connected to those substrates via bonding wires.

Thus, according to the semiconductor package structure of the invention and the fabrication method thereof, it basically involves first forming one or more openings on the substrate at positions based on the arrangement of the bond pads of the semiconductor chip, so that when the substrate is attached to the active surface of the semiconductor chip, the bond pads on the active surface are exposed through the opening, or, alternatively, a plurality of substrates are arranged on the active surface of the semiconductor chip in such a way that the bond pads are exposed so as to permit electrical connection between the bond pads of the semiconductor chip and the substrates. Then the substrates are electrically connected to a leadframe having a plurality of leads, followed by forming an encapsulant for encapsulating the substrates, semiconductor chip, and the leadframe, wherein the bottom surfaces of the leads are exposed from the encapsulant, serving as electrical connections for the package to an external device, such that a compact and thin package without extended leads is formed that can be used in semiconductor chips having different bond pad arrangements.

In addition, in the semiconductor package of the invention, the top surface of the leads of the leadframe can be provided exposed from the encapsulant, such that stacking can be achieved by linking the bottom surface of the leads of one package to the exposed top surface of the outer portion of the leads of another package,

Moreover, in the semiconductor package of the invention, passive components can be also included attached to the substrate, so as to improve the overall electrical functionality and performance of the package.

In comparison with the conventional technology, the semiconductor package of the invention and the fabricating method thereof can be used in packaging semiconductor chips with different bond pad arrangements, and is compact and thin in structure without the extended leads. Moreover, the package can be easily stacked on top of another like package, and, furthermore, the electrical functionality can be improved by the inclusion of passive components in the package.

### BRIEF DESCRIPTION OF THE DRAWINGS

The present invention can be more fully understood by reading the following detailed description of the preferred embodiments, with reference made to the accompanying drawings, wherein:

FIG. 1 is a perspective view of a conventional Thin Small Outline Package (TSOP);

FIG. 2 is a cross-sectional view of a Chip on Lead Thin Small Outline Package (COL TSOP);

FIG. 3 is a cross-sectional view of a semiconductor package disclosed by U.S. Pat. No. 5,363,279;

FIG. 4A is a cross-sectional view of two stacked semiconductor packages as disclosed by U.S. Pat. No. 5,986,209;

FIG. 4B is a cross-sectional view of two stacked Dual Flat No Lead (DFN) packages as disclosed by U.S. Pat. No. 6,630,729;

FIG. 5A is a top view of an array of semiconductor packages in accordance with the first preferred embodiment of the present invention;

FIGS. 5B to 5E are cross-sectional views showing the fabrication method of the semiconductor package in accordance with the first preferred embodiment of the present invention;

FIGS. 6A to 6D are cross-sectional views showing the fabrication method of the semiconductor package in accordance with the second preferred embodiment of the invention;

FIG. 7 is a cross-sectional view showing the semiconductor package of the third preferred embodiment of the invention;

FIG. 8 is a cross-sectional view showing the semiconductor package of the fourth preferred embodiment of the invention;

FIGS. 9A to 9D are cross-sectional views showing the fabrication method of the semiconductor package of the fifth preferred embodiment of the invention.

FIG. 10 is a cross-sectional view showing the semiconductor package of the sixth preferred embodiment of the invention;

FIGS. 11A and 11B are cross-sectional views showing the semiconductor package of the seventh preferred embodiment of the invention;

FIGS. 12A and 12B are cross-sectional views showing the semiconductor package of the eighth preferred embodiment of the invention;

FIGS. 13A and 13D are cross-sectional views showing the semiconductor package of the ninth preferred embodiment of the invention.

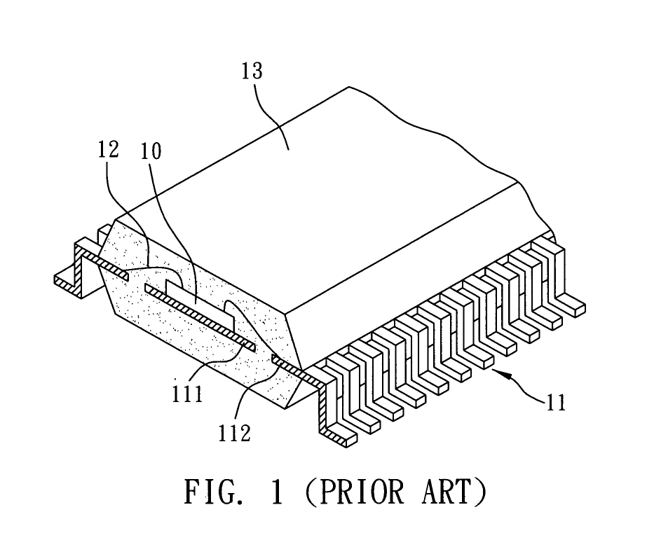

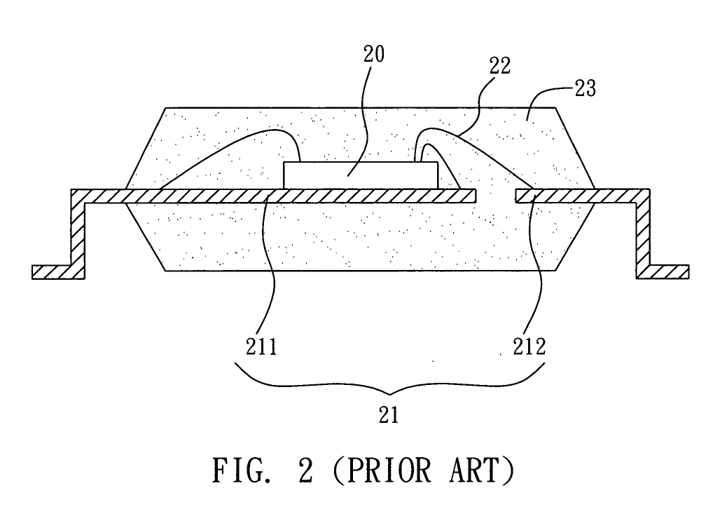

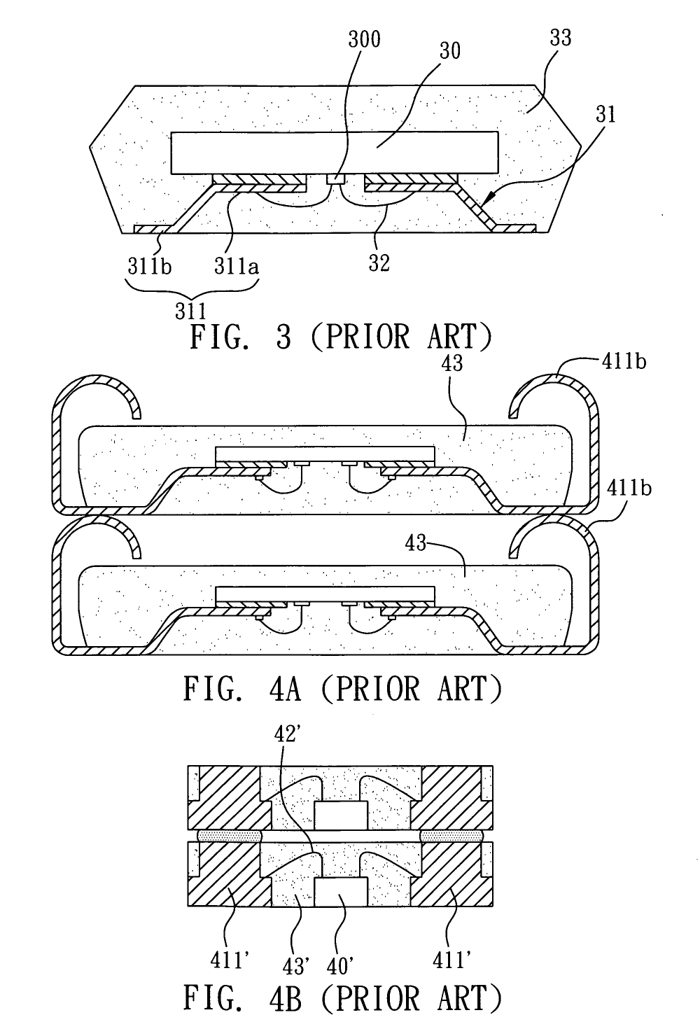

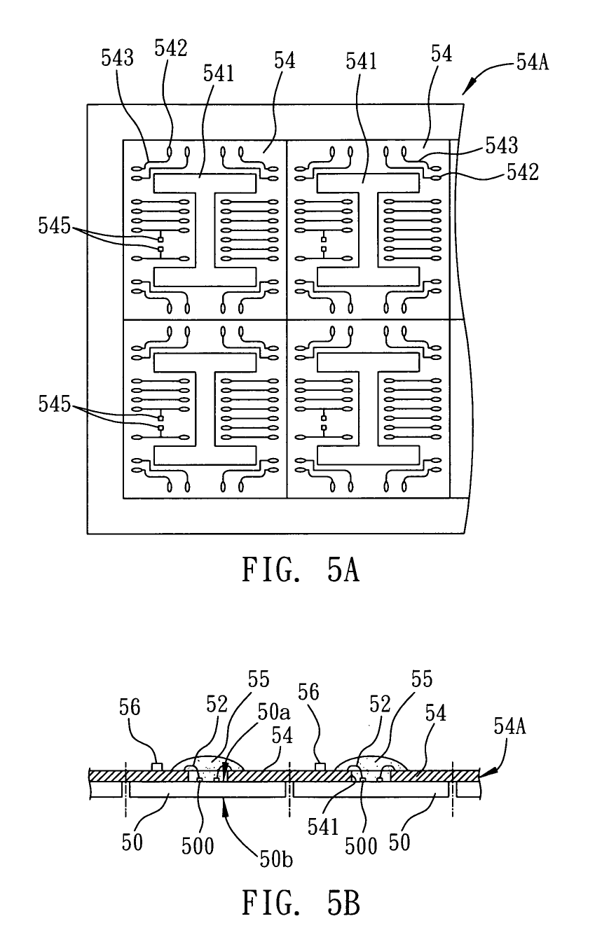

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the invention. The present invention may also be implemented and applied according to other embodiments, and the details may be modified based on different views and applications without departing from the spirit of the invention.

### First Preferred Embodiment

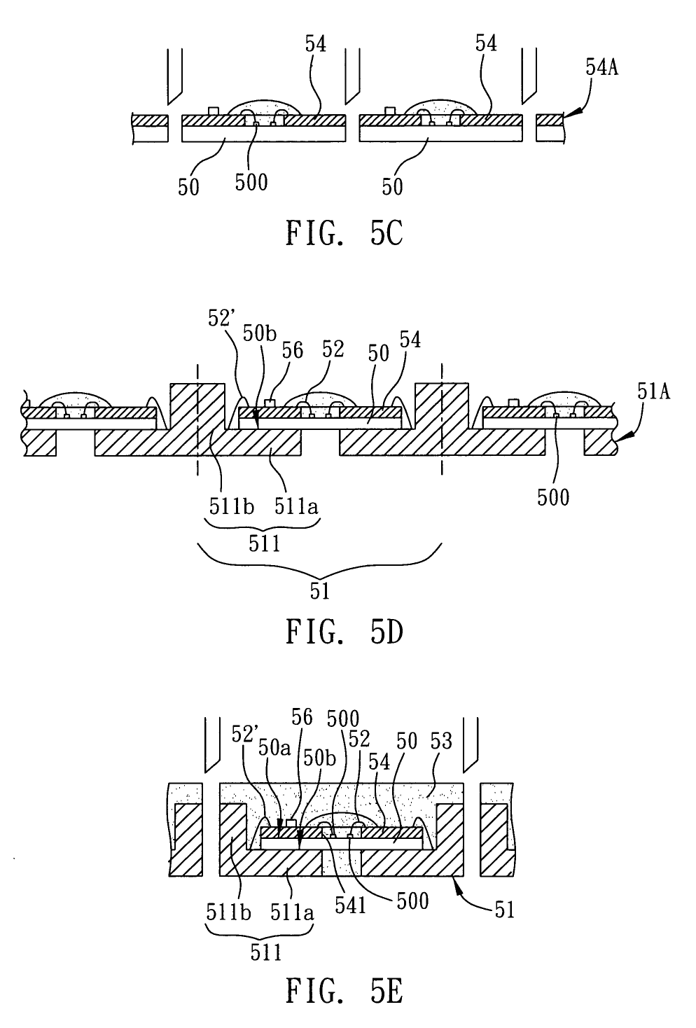

Referring to FIGS. 5A to 5E, top and cross-sectional views of the semiconductor package of the invention and the fabricating method thereof are shown.

The first embodiment of the invention is carried out in batches (hence the array of substrate modules 54A in FIG. 5A), so as to increase fabrication yield, however it can also be carried out as a single fabrication.

As shown in FIG. 5A, a substrate module 54A having a plurality of substrates 54 is provided. Each of the substrates 54 has at least one opening 541 and the arrangement of the opening 541 is based on the arrangement of bond pads disposed on the active surface of the semiconductor chip. In the present embodiment, as the bond pads on the active surface of the semiconductor chip are arranged in an I-shape, the corresponding opening 541 is an I-shaped opening. In addition, a plurality of electrical connection pads 542 and conductive circuits 543 are formed on the substrate 54 to provide electrical connections for the semiconductor chip. Bonding pads 545 for passive components, such as resistors and capacitors to be attached thereon, are also provided on the substrate surface.

As shown in FIG. 5B, next, a semiconductor 50 having an active surface 50a and an opposing non-active surface 50b is attached to the substrate 54 in a manner that the active surface 50a is attached to the substrate 54. A plurality of bond pads 500 arranged in I-shape are disposed on the active surface 50a of the semiconductor chip 50 at the positions corresponding to the I-shaped opening 541, allowing the bond pads 500 to be exposed. Bonding wires 52 are provided to pass through the opening 541 of the substrate to electrically connect the bond pads 500 of the semiconductor chip 50 to the electrical connection pads 542 of the substrate 54. Moreover, an insulative material 55 is filled within the opening 541 of the substrate 54 so as to cover the bonding wires 52. In addition, the substrate 54 has at least one passive component bond pad 545 formed thereon allowing at least one passive component 56 to be attached thereon, so as to increase the electrical functionality.

As shown in FIG. 5C, a singulation process is performed on the substrate module 54A to singulate the plurality of semiconductor chips 50 each coupled with a substrate 54. In the present embodiment, the size of the substrate 54 is substantially the same as the size of the semiconductor chip 50.

As shown in FIG. 5D, a leadframe module 51A having a plurality of leadframes 51 is provided. Each of the leadframes 51 has a plurality of leads 511, and each of the leads 511 has an inner portion 511a and an outer portion 511b. The outer portion 511b is higher than the inner portion 511a so as to position the semiconductor chip 50 coupled with the substrate 54 on the leadframe 51. In the present embodiment, the non-active surface 50b of semiconductor chip 50 coupled with the substrate 54 is physically attached to the inner portions 511a of the leads 511 of the leadframe 51, and the substrate 54 is electrically connected to the inner portions 511a of the leads 511 via bonding wires 52′, the formation of inner portion 511a and outer portion 511b with a differential height being achieved by half-etching.

As shown in FIG. 5E, a molding process is performed to form an encapsulant 53 for encapsulating the substrate 54, semiconductor chip 50, bonding wires 52′ and the leadframe 51, allowing at least the bottom surface of the leads 511 of the leadframe 51 to be exposed from the encapsulant 53. Then, a singulation or punch process is performed to singulate each leadframe 51, so as to form a single semiconductor package of the present invention.

Accordingly, as shown in FIG. 5E, the semiconductor package of the invention comprises a semiconductor chip 50 having an active surface 50a, whereon a plurality of bond pads 500 are formed, and an opposing non-active surface 50b; a substrate 54 physically coupled with the active surface 50a of the semiconductor chip 50, having an opening 541 for exposing the bond pads 500; bonding wires passing through the opening for electrically connecting the bond pads 500 and the substrate 54; a leadframe 51 for carrying and electrically connecting the semiconductor chip 50 coupled with the substrate 54, wherein the leadframe 51 has a plurality of leads 511, each of which has a inner portion 511a and an outer portion 511b that is higher than the inner portion 511a, allowing the semiconductor chip 50 and the substrata 54 to be attached to the inner portion 511a of the lead 511; and an encapsulant 53 for encapsulating the semiconductor chip 50, substrate 54 and the leadframe 51, allowing at least the bottom surface of the leads 511 to be exposed. Moreover, passive components can be attached on the substrate 54 in the semiconductor package, improving the overall electrical functionality and performance of the package.

In accordance with the semiconductor package structure of the invention and the fabricating method thereof, an opening is formed in advance on the substrate based on the arrangement of the bonding pads, so that when the active surface of the semiconductor chip is attached to the substrate, the bond pads disposed on the active surface are exposed from the opening, allowing the bond pads of the semiconductor package to be electrically connected to the substrate. Subsequently, a semiconductor chip that is coupled to a substrate is attached and electrically connected to a leadframe having a plurality of leads. Then, an encapsulant is formed to encapsulate the substrate, semiconductor chip, and the leadframe, in such a way that the bottom surfaces of the leads are exposed from the encapsulant so as to allow the package to be electrically connected to an external device. Accordingly, a thin and compact package without extended leads is formed, applicable in packaging various semiconductor chips having different arrangements of bond pads.

### Second Preferred Embodiment

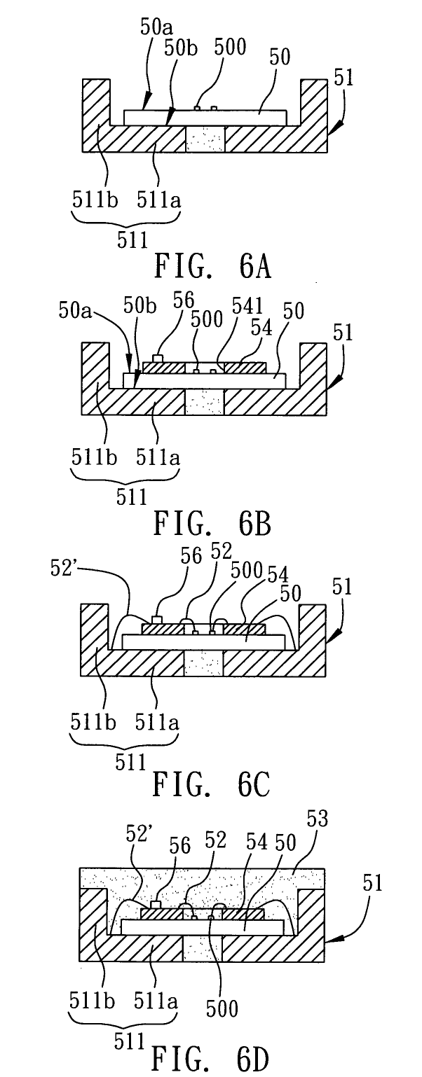

Referring to FIG. 6A, a leadframe 51 having a plurality of leads 511 is provided. Each lead 511 has an inner portion 511a and an outer portion 511b that are formed with differing heights. The height of the outer portion 511b of each lead 511 is larger than the height of the inner portion 511a of each lead 511, wherein the semiconductor chip 50 is attached to the inner portions 5111a of the leads 511. The semiconductor chip 50 has an active surface 50a and an opposing non-active surface 50b, and is attached to the inner portion 511a of the leads 511 via its non-active surface 50b. Also, the active surface 50a of the semiconductor chip 50 has bond pads 500 disposed thereon.

As shown in FIG. 6B, the active surface 50a of the semiconductor chip is attached to the substrate 54. The substrate 54 has an opening 541 at a position based on the arrangement of the bond pads 500 disposed on the active surface 50a of the semiconductor chip 50, allowing the bond pads 500 to be exposed from the opening 541. In addition, passive components 56 can be attached on the substrate. The size of the substrate 54 can be larger, equal to, or smaller than the size of the semiconductor chip 50.

As shown in FIG. 6C, bonding wires 52 and 52′ are used to electrically connect the bonding pads 500 of the semiconductor chip 50 to the substrate 54, and electrically connect the substrate 54 to the inner portions of the leads 5111a of the leadframe 51.

As shown in FIG. 6D, an encapsulant 53 is formed on the leadframe 51 for encapsulating the substrate 54, semiconductor chip 50, bonding wires 52, 52′ and the leadframe 51, allowing at least the bottom surfaces of the leads 511 of the leadframe 51 to be exposed from the encapsulant 53.

Moreover, in the present embodiment, the wire bonding process between the substrate 54 and the leadframe 51 can be implemented immediately after the wire bonding process between the bond pads 500 of the semiconductor chip 50 and the substrate 54, eliminating the step of filling the openings of the substrate 54 with an insulative material, thereby providing a simpler fabrication process.

### Third Preferred Embodiment

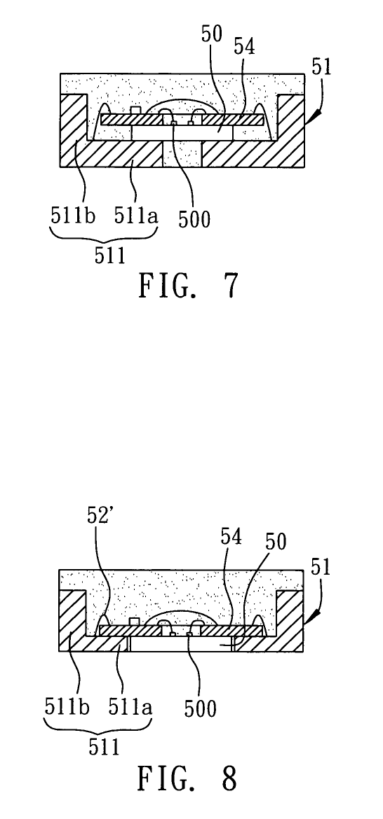

As shown in FIG. 7, a cross-sectional view of the semiconductor package of the third preferred embodiment of the invention is shown.

The third preferred embodiment of the invention is almost the same as the forgoing first preferred embodiment. The major difference is that, in the present embodiment, the size of the substrate 54 is larger than the size of the semiconductor chip 50, but, as before, the semiconductor chip 50 is attached to the inner portion 511a of each of the leads 511, while the substrate 54 is attached on the semiconductor chip 50 and is electrically connected to the inner portions 511a of the leads 511 of the leadframe 51.

### Fourth Preferred Embodiment

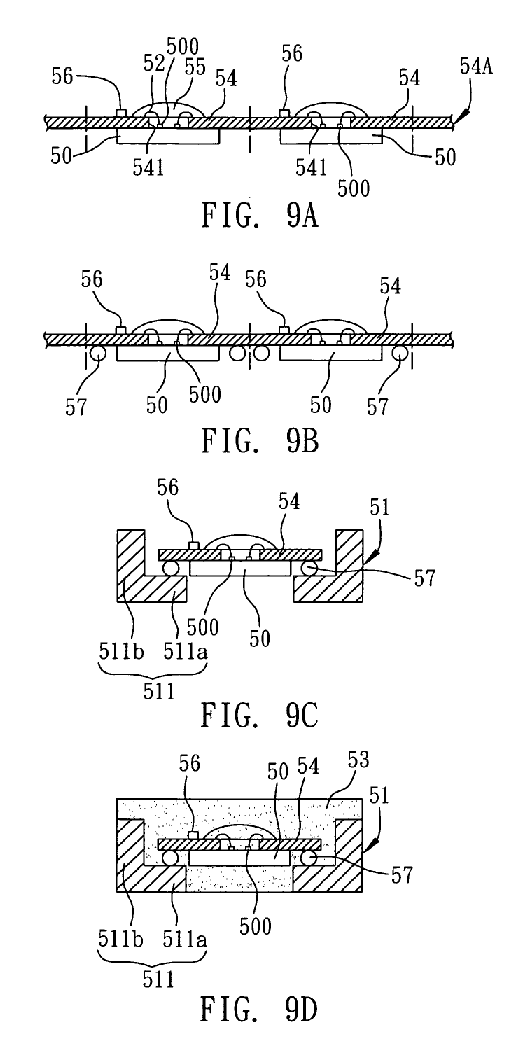

Referring to FIG. 8, a cross-sectional view of the semiconductor package of the fourth preferred embodiment of the invention is shown.

The fourth preferred embodiment of the invention is almost the same as the foregoing first preferred embodiment. The major difference is that, in the present embodiment, the size of the substrate 54 is larger than the size of the semiconductor chip 50 and the semiconductor chip 50 is accommodated between the opposed two inner portions 511a of the leads 511 on each lead-bearing side of the leadframe 51, as opposed to on top of them. Moreover, the non-active surface of the semiconductor chip 50 is exposed from the encapsulant, so as to increase heat-dissipating efficiency.

### Fifth Preferred Embodiment

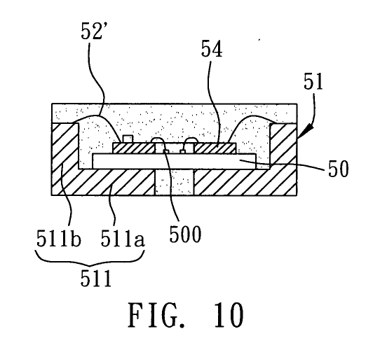

Referring to FIG. 9A to 9D, cross-sectional views of the semiconductor package of the fifth preferred embodiment of the invention and the fabricating method thereof are shown.

The fifth preferred embodiment of the invention is almost the same as the foregoing fourth preferred embodiment. The major difference is that—although the size of the substrate is larger than the semiconductor chip 50—the substrate is attached and electrically connected directly to the inner portion of the leads via conductive material without the use of bonding wires 52′, and the semiconductor chip is accommodated between such conductive material and/or between the two inner portions of the leads.

As shown in FIG. 9A, a substrate module 54A having a plurality of substrates 54 is provided for semiconductor chips 50 to be attached on the substrates 54. Each substrate has at least one opening 541 for exposing the corresponding bond pads 500 on the active surface of the semiconductor chip 50. Then, bonding wires are used to electrically connect the bond pads 500 of the semiconductor chip to the top surface of the substrate 54. The opening 541 is then filled with an insulative material 55 for encapsulating the bonding wires 52. Meanwhile at least one passive component 56 is attached and electrically connected to the top surface of the substrate, so as to improve the electronic functionality.

As shown in FIG. 9B, on the bottom surface of the substrate 54, a plurality of conductive components such as solder balls are formed.

As shown in FIG. 9C, a singulation process is performed to singulate out each substrate. Then, a leadframe 51 having a plurality of leads is provided whereto the semiconductor chip 50 coupled with the substrate 54 is attached. The substrate 54 is electrically connected to the leads 511 of the leadframe 51 via the solder balls 57. Each lead 511 has an inner portion 511a and an outer portion 511b that are formed with differing heights. The height of the outer portion 511b of each lead 511 is larger than the inner portion 511a of each lead 511 and the substrate 54 is attached and electrically connected to the inner portion 5111a of the leads 511 via the solder balls 57.

As shown in FIG. 9D, a molding process is performed to form an encapsulant 53 for encapsulating the semiconductor chip 50, substrate, and the leadframe 51, in such a way that at least the bottom surfaces of the leads 511 are exposed.

### Sixth Preferred Embodiment

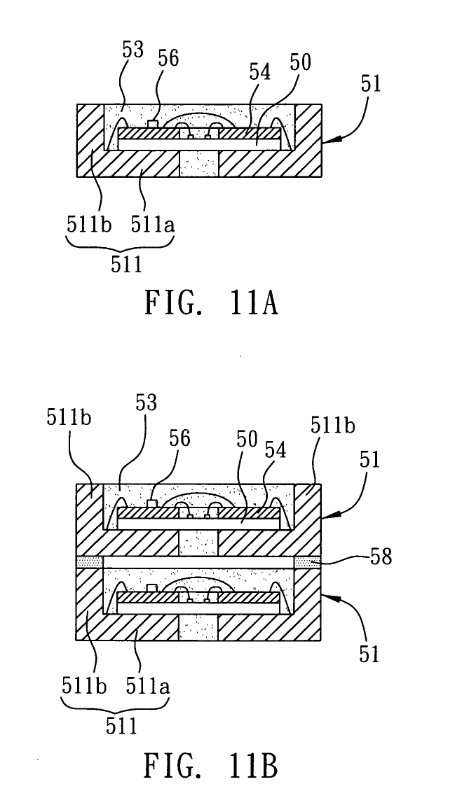

Referring to FIG. 10, a cross-sectional view of the sixth preferred embodiment of the semiconductor package of the invention is shown.

The sixth preferred embodiment of the invention is almost the same as the foregoing first preferred embodiment. The major difference is that, in the present embodiment, when forming electrical connections between the substrate 54 and the leadframe 51, the substrate can not only be electrically connected to the inner portion 511a of the leads 511 (such connection not being shown in FIG. 10), but it can also be electrically connected to the outer portion 511b of the lead via the bonding wires 52′. The size of the substrate attached on the semiconductor chip can be larger, smaller, or equal to the size of the semiconductor chip.

### Seventh Preferred Embodiment

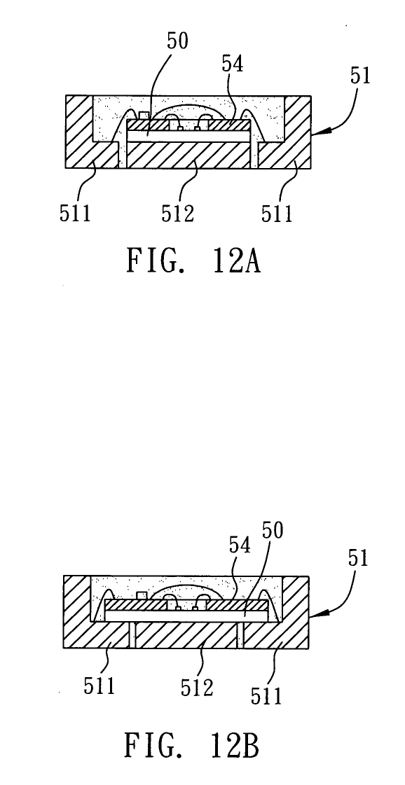

Referring to FIGS. 11A and 11B, cross-sectional views of the semiconductor package of the seventh preferred embodiment of the invention are shown.

The seventh preferred embodiment is almost the same as the foregoing first preferred embodiment. The major difference is that, in the present embodiment, the top surface of the outer portion 11b of the leads 511 of the leadframe 51 is exposed from the encapsulant. By this way, stacking can be achieved by linking the bottom surface of the leads 511 of an upper package to the exposed top surface of the outer portion 511b of the lead 511 of a lower package.

### Eighth Preferred Embodiment

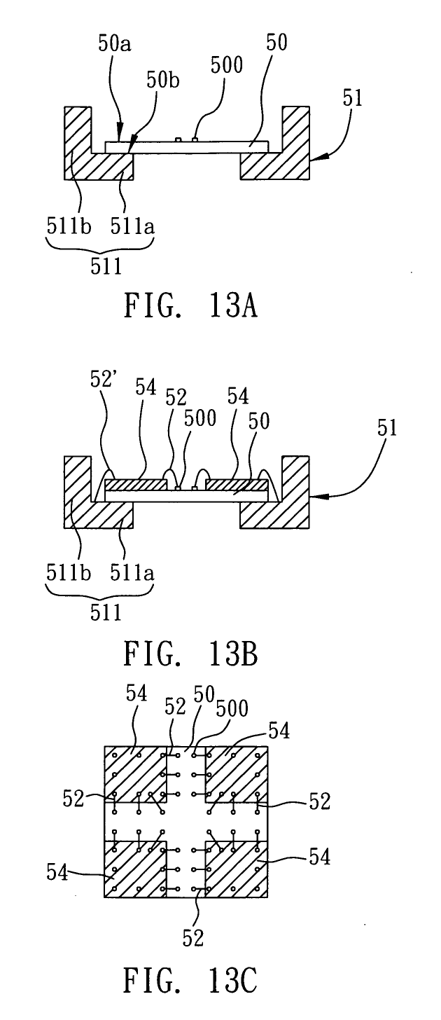

Referring to FIGS. 12A to 12B, cross-sectional views of the semiconductor package of the eighth preferred embodiment of the invention are shown.

The eighth preferred embodiment is almost the same as the foregoing first preferred embodiment. The major difference is that, in the present embodiment, the leadframe 51 comprises a die pad 512 and leads formed on at least two sides of the leadframe for the substrate 54 and the semiconductor chip 50 to be attached onto the die pad 512 or on the die pad 512 and the leads 511, allowing the die pad 512 and the bottom surface of the leads to be exposed from the encapsulant, thereby improving the heat dissipating efficiency of the semiconductor chip 50 via the die pad 512.

### Ninth Preferred Embodiment

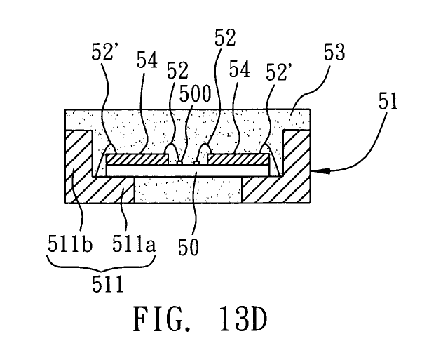

Referring to FIGS. 13A to 13D, cross-sectional views of the semiconductor package of the ninth preferred embodiment of the invention and the fabricating method thereof are shown.

The ninth preferred embodiment is almost the same as the foregoing second preferred embodiment. The major difference is that, in the present embodiment, a plurality of substrates are disposed on the active surface of the semiconductor chip in such a way that the bond pads on the active surface of the semiconductor chip are exposed for electrically connecting the bond pads of the semiconductor chip to the substrate.

As shown in FIG. 13A, a semiconductor chip having an active surface 50a and an opposing non-active surface 50b is attached to the leadframe 51 having a plurality of leads 511. A plurality of bond pads 500 is disposed on the active surface 50a of the semiconductor chip and the semiconductor chip 50 is attached to the leadframe 51 via its non-active surface 50b.

As shown in FIG. 13B, a plurality of substrates 54 is disposed on the semiconductor chip 50 at positions that allow the bond pads 500 on the active surface 50a of the semiconductor chip 50 to be exposed. Through a wire bonding process, bonding wires 52, 52′ are used to electrically connect the bond pads 500 on the semiconductor chip 50 to the substrate 54 and electrically connect the substrate 54 to the leadframe 51, respectively. Moreover, referring to FIG. 13C, a planar view is shown of the situation where substrates 54 are disposed on the semiconductor chip 50 and the process of wire bonding. Only four substrates 54 are shown disposed on the semiconductor chip 50 in this figure; however, the scope of the invention is not limited to this number or physical layout. On the contrary, the design can be varied according to the practical electrical requirements and bond pad arrangement.

As shown in FIG. 13D, a molding process is performed to form an encapsulant 53 that encapsulates the semiconductor chip 50, substrate 54, bonding wires 52, 52′ and leadframe 51, allowing the bottom surface of the leads 511 of the leadframe 5 to be exposed from the encapsulant 53.

Certainly, in the fabricating method of the present embodiment, it is also feasible to attach the substrate to the semiconductor chip prior to attachment of the semiconductor chip that is coupled to the substrate. It should be noted that, in practice, numerous variations can be provided by combining various features of the preceding embodiments.

Accordingly, through this separated substrate design for the semiconductor chip of the ninth embodiment, the material cost of the substrate can be reduced. Moreover it is feasible to perform the wire bonding process between the bond pads and the substrate, and between the substrate and the leadframe at the same time, eliminating the process of filling the substrate opening with the insulative material, thereby speeding up the fabricating process.

Thus, according to the semiconductor package structure of the invention and the fabricating method thereof, the method basically involves forming an opening in the substrate at one or more positions based on the pre-existing arrangement of the bond pads of the semiconductor chip, so that when the substrate is attached to the active surface of the semiconductor chip, the bond pads on the active surface are exposed through the one or more openings, or, alternatively, a plurality of substrates are arranged on the active surface of the semiconductor chip in such a way that the bond pads are exposed so as to permit electrical connation between the bond pads of the semiconductor chip and the substrates. Then, the substrates are electrically connected to a leadframe having a plurality of leads, followed by forming an encapsulant for encapsulating the substrates, semiconductor chip, and the leadframe, wherein the bottom surfaces of the leads are exposed from the encapsulant, serving as an electrical connection for the package to an external device, such that a compact and thin package without extended leads is formed that can be used in semiconductor chips having differing bond pad arrangements.

In addition, in the semiconductor package of the invention, passive components can also be attached to the substrate, so as to improve the overall electrical functionality and performance of the package.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor package, comprising:
a semiconductor chip having an active surface, a non-active surface opposing to the active surface, and a plurality of bond pads formed on the active surface;
a substrate attached on the active surface of the semiconductor chip in such a way that the bond pads are exposed;
a plurality of bonding wires electrically connecting the bond pads of the semiconductor chip with the substrate;
a leadframe having a plurality of leads, for carrying and electrically connecting the semiconductor chip, which is electrically connected to the substrate; and
an encapsulant for encapsulating the semiconductor chip, substrate, and leadframe except bottoms surface of the leads.

2. The semiconductor package of claim 1, wherein each of the leads comprises an inner portion and an outer portion having differing heights, wherein the outer portion is higher than the inner portion, and the chip and the substrate are both attached to the inner portion.

3. The semiconductor package of claim 1, wherein a top surface of the outer region is exposed from the encapsulant, so as to electrically connect the exposed bottom surface of the leads of an upper package to the exposed top surface of the outer portion of the leads of a lower package via a conductive adhesive material, so as to form a stacking structure.

4. The semiconductor package of claim 2, wherein the substrate is larger than the semiconductor chip is size, allowing the substrate to be attached to the inner portion of the leads and accommodating the semiconductor chip between the inner portions of opposing leads.

5. The semiconductor package of claim 4, wherein the non-active surface of the semiconductor chip is exposed from the encapsulant.

6. The semiconductor package of claim 2, wherein the substrate is electrically connected to either of the inner portion and the outer portion of the leads via bonding wires.

7. The semiconductor package of claim 2, further comprising at least one passive component attached on the substrate.

8. The semiconductor package of claim 1, wherein the substrate attached on the semiconductor chip has at least one opening for exposing the bond pads on the active surface of the chip.

9. The semiconductor package of claim 8, wherein the shape of the opening is based on the arrangement of the bond pads disposed on the active surface of the semiconductor chip.

10. The semiconductor package of claim 1, further comprising an insulative material for covering the bonding wires that are used to electrically connect the semiconductor chip and the substrate.

11. The semiconductor package of claim 1, wherein multiple substrates are provided and the substrates are arranged in such a way that the bond pads are exposed.

12. The semiconductor package of claim 1, wherein the size of the substrate can be larger, smaller, or equal to the size of the semiconductor chip.

13. The semiconductor package of claim 1, wherein the substrate is electrically connected to the leadframe via bonding wires or conductive materials.

14. The semiconductor package of claim 1, wherein the leadframe further comprises a die pad for attaching a semiconductor chip thereon.

15. A fabricating method of the semiconductor package, comprising:
preparing a semiconductor chip having an active surface whereon a plurality of bond pads is formed and an opposing non-active surface, which is attached to a substrate via the active surface of the semiconductor chip in such a way that the bond pads are exposed for electrically connecting with the substrate;
attaching and electrically connecting the semiconductor chip that is coupled with the substrate to a leadframe having a plurality of leads;
forming an encapsulant for encapsulating the semiconductor chip, substrate, and leadframe in such a way that at least the bottom surfaces of the leads of the leadframe are exposed from the encapsulant.

16. The fabricating method of the semiconductor package of claim 15, wherein each lead is divided into an inner portion and an outer portion having differing heights, wherein the height of the outer portion of each lead is larger than the height of the inner portion of each lead, and the chip with the substrate is attached to the inner portion of the leads.

17. The fabricating method of the semiconductor package of claim 16, wherein the top surface of the outer region is exposed from the encapsulant, so as to electrically connect the exposed bottom surface of the leads of an upper package to the exposed top surface of the outer portion of the leads of a lower package via conductive adhesive material, so as to form a stacking structure.

18. The fabricating method of the semiconductor package of claim 16, wherein the size of the substrate is larger than the size of the semiconductor chip, allowing the substrate to be attached to the inner portion of the leads and accommodating the semiconductor chip between the inner portions of opposing leads.

19. The fabricating method of the semiconductor package of claim 18, wherein the non-active surface of the semiconductor chip is exposed from the encapsulant.

20. The fabricating method of the semiconductor package of claim 16, wherein the substrate is electrically connected to either the inner portion or the outer portion of the leads via bonding wires.

21. The fabricating method of the semiconductor package of claim 15, further comprising at least one passive component attached on the substrate.

22. The fabricating method of the semiconductor package of claim 15, wherein the substrate attached on the semiconductor chip has at least one opening for exposing the bond pads on the active surface of the chip.

23. The fabricating method of the semiconductor package of claim 22, wherein the shape of the opening is based on the arrangement of bond pads disposed on the active surface of the semiconductor chip.

24. The fabricating method of the semiconductor package of claim 15, further comprising an insulative material for covering the bonding wires that are used to electrically connect the semiconductor chip and the substrate.

25. The fabricating method of the semiconductor package of claim 15, wherein multiple substrates are provided, and the substrates are arranged in such a way that the bond pads are exposed.

26. The fabricating method of the semiconductor package of claim 15, wherein the size of the substrate can be larger, smaller, or equal to the size of the semiconductor chip.

27. The fabricating method of the semiconductor package of claim 15, wherein the substrate is electrically connected to the leadframe via bonding wires or conductive materials.

28. The fabricating method of the semiconductor package of claim 27, wherein forming electrical connections between the substrate and the semiconductor chip and between the substrate and the leadframe can be performed at the same time using wire bonding.

29. The fabricating method of the semiconductor package of claim 15, wherein the leadframe further comprises a die pad for attaching a semiconductor chip thereon.

30. A fabricating method of the semiconductor package, comprising:
preparing a semiconductor chip having an active surface whereon a plurality of bond pads is formed and an opposing non-active surface, the semiconductor chip being attached to a substrates via the active surface of the semiconductor chip;
disposing the substrate on the active surface of the semiconductor chip in such a way that the bond pads are exposed;
electrically connecting the substrate to the semiconductor chip and electrically connecting the substrate to the leadframe; and
forming an encapsulant for encapsulating the semiconductor chip, substrate, and leadframe in such a way that at least the bottom surfaces of the leads of the leadframe are exposed from the encapsulant.

31. The fabricating method of the semiconductor package of claim 30, wherein each lead is divided into an inner portion and an outer portion having differing heights, wherein the height of the outer portion of each lead is larger than the height of the inner portion of each lead, and the chip with the substrate is attached to the inner portion of the leads.

32. The fabricating method of the semiconductor package of claim 31, wherein the top surface of the outer region is exposed from the encapsulant, so as to electrically connect the exposed bottom surface of the leads of an upper package to the exposed top surface of the outer portion of the leads of a lower package via conductive adhesive material, so as to form a stacking structure.

33. The fabricating method of the semiconductor package of claim 32, wherein the size of the substrate is larger than the size of the semiconductor chip, allowing the substrate to be attached to the inner portion of the leads and accommodating the semiconductor chip between the inner portions of opposing leads.

34. The fabricating method of the semiconductor package of claim 31, wherein the non-active surface of the semiconductor chip is exposed from the encapsulant.

35. The fabricating method of the semiconductor package of claim 30, wherein the substrate is electrically connected to either the inner portion or the outer portion of the leads via bonding wires.

36. The fabricating method of the semiconductor package of claim 30, further comprising at least one passive component attached on the substrate.

37. The fabricating method of the semiconductor package of claim 30, wherein the substrate attached on the semiconductor chip has at least one opening for exposing the bond pads on the active surface of the chip.

38. The fabricating method of the semiconductor package of claim 30, wherein the shape of the opening is based on the arrangement of bond pads disposed on the active surface of the semiconductor chip.

39. The fabricating method of the semiconductor package of claim 30, further comprising an insulative material for covering the bonding wires that are used to electrically connect the semiconductor chip and the substrate.

40. The fabricating method of the semiconductor package of claim 30, wherein multiple substrates are provided, and the substrates are arranged in such a way that the bond pads are exposed.

41. The fabricating method of the semiconductor package of claim 30, wherein the size of the substrate can be larger, smaller, or equal to the size of the semiconductor chip.

42. The fabricating method of the semiconductor package of claim 41, wherein forming electrical connections between the substrate and the semiconductor chip and between the substrate and the leadframe can be performed at the same time using wire bonding.

43. The fabricating method of the semiconductor package of claim 30, wherein the leadframe further comprises a die pad for attaching a semiconductor chip thereon.
